(19) United States
(12) Patent Application Publication
(10) Pub. No.: US 2024/0066657 A1
(43) Pub. Date: Feb. 29, 2024

(54) CONTROL METHOD, CONTROL APPARATUS, TRAINING METHOD, AND TRAINING APPARATUS BASED ON THICKNESS ESTIMATION OF WAFER SUBSTRATE

(71) Applicant: KCTECH CO., LTD., Gyeonggi-do (KR)

(72) Inventors: Ji Hoon SON, Gyeonggi-do (KR); Jeong Heon HAN, Seoul (KR); Ki Hyuk YANG, Gyeonggi-do (KR)

(73) Assignee: KCTECH CO., LTD., Gyeonggi-do (KR)

(21) Appl. No.: 18/140,977

(22) Filed: Apr. 28, 2023

(30) Foreign Application Priority Data
Aug. 23, 2022 (KR) 10-2022-0105663

(51) Int. Cl. B24B 37/005; G01B 11/06; G01N 21/31; G06N 3/08

(52) U.S. Cl. CPC B24B 37/005; G01B 11/06; G01N 21/31; G06N 3/08

(57) ABSTRACT

Provided are a control method, a control apparatus, a training method, and a training apparatus based on thickness estimation of a wafer substrate. The training method includes generating a training spectrum signal according to a thickness of a wafer substrate using an optical model, generating a training spectrum signal having a noise by applying a noise based on a noise parameter to the training spectrum signal, calculating a similarity between the training spectrum signal having the noise and an actually measured spectrum signal, and when the similarity satisfies a set condition, training a noise reduction model using the training spectrum signal having the noise.

### CROSS-REFERENCE TO RELATED APPLICATION

This application claims the benefit of Korean Patent Application No. 10-2022-0105663 filed on Aug. 23, 2022, in the Korean Intellectual Property Office, the entire disclosure of which is incorporated herein by reference for all purposes.

### BACKGROUND

### 1. Field of the Invention

One or more embodiments relate to a control technology and a training technology for estimating a thickness of a wafer substrate.

### 2. Description of the Related Art

In manufacturing a wafer substrate, a chemical mechanical polishing (CMP) process including polishing, buffing and cleaning is required. The CMP process of the wafer substrate requires a process of polishing a surface to be polished of the wafer substrate using a polishing pad. A CMP apparatus is a component for polishing, buffing, and cleaning one or both surfaces of a wafer substrate, and includes a carrier for supporting a wafer substrate and a polishing pad for physically making a surface of the wafer substrate to be worn.

### SUMMARY

According to an aspect, there is provided a training method including generating a training spectrum signal according to a thickness of a wafer substrate using an optical model, generating a training spectrum signal having a noise by applying a noise based on a noise parameter to the training spectrum signal, calculating a similarity between the training spectrum signal having the noise and an actually measured spectrum signal, and when the similarity satisfies a set condition, training a noise reduction model using the training spectrum signal having the noise.

According to another aspect, there is provided a control method including receiving a spectrum signal including thickness information of a wafer substrate from a spectroscopic monitoring device, determining a noise parameter for a noise included in the spectrum signal using a noise reduction model configured to receive the spectrum signal as an input, performing a noise reduction process of reducing a noise from the spectrum signal based on the determined noise parameter, and determining an estimated thickness value of the wafer substrate using a thickness estimation model configured to receive the spectrum signal having the reduced noise as an input.

According to still another aspect, there is provided a training apparatus including a processor, and a memory configured to store instructions executable by the processor. The executable instructions may cause the processor to perform a plurality of operations including generating a training spectrum signal according to a thickness of a wafer substrate using an optical model, generating a training spectrum signal having a noise by applying a noise based on a noise parameter to the training spectrum signal, calculating a similarity between the training spectrum signal having the noise and an actually measured spectrum signal, and when the similarity satisfies a set condition, training a noise reduction model using the training spectrum signal having the noise.

According to still another aspect, there is provided a control apparatus including a processor, and a memory configured to store instructions executable by the processor. The executable instructions may cause the processor to perform a plurality of operations including receiving a spectrum signal including thickness information of a wafer substrate from a spectroscopic monitoring device, determining a noise parameter for a noise included in the spectrum signal using a noise reduction model configured to receive the spectrum signal as an input, performing a noise reduction process of reducing a noise from the spectrum signal based on the determined noise parameter, and determining an estimated thickness value of the wafer substrate using a thickness estimation model configured to receive the spectrum signal having the reduced noise as an input.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating an overview of a training process according to an embodiment;

FIG. 2 is a flowchart illustrating operations of a training method according to an embodiment;

FIG. 3 is a block diagram illustrating a configuration of a training apparatus according to an embodiment;

FIG. 4 is a diagram illustrating an overview of a control process of controlling a polishing apparatus for a wafer substrate according to an embodiment;

FIG. 5 is a flowchart illustrating operations of a control method according to an embodiment;

FIG. 6 is a block diagram illustrating a configuration of a control apparatus according to an embodiment;

FIG. 7 is a diagram illustrating a training spectrum signal generated by an optical model according to an embodiment;

FIGS. 8A and 8B are diagrams illustrating training spectrum signals having a noise generated by a generative adversarial network according to an embodiment;

FIG. 9 is a diagram illustrating a spectrum signal that is actually measured and a resultant signal obtained by performing a noise reduction process using a noise reduction model according to an embodiment;

FIG. 10 is a block diagram of a conditioning system for a wafer substrate according to an embodiment;

FIG. 11 is a perspective view of a polishing apparatus according to an embodiment; and

FIG. 12 is a plan view of a polishing apparatus according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one constituent element from another constituent element, and the nature, the sequences, or the orders of the constituent elements are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

As used in connection with various embodiments of the disclosure, the term “module” may include a unit implemented in hardware, software, or firmware, and may interchangeably be used with other terms, for example, “logic”, “logic block”, “part”, or “circuitry”. A module may be a single integral component, or a minimum unit or part thereof, adapted to perform one or more functions. For example, according to an embodiment, the module may be implemented in a form of an application-specific integrated circuit (ASIC).

The same name may be used to describe an element included in the embodiments described above and an element having a common function. Unless otherwise mentioned, the descriptions of the embodiments may be applicable to the following embodiments and thus, duplicated descriptions will be omitted for conciseness.

A technology described herein includes a technology for processing a noise of a spectral signal (e.g., a spectrum signal) using a machine learning system. In a case of polishing a wafer substrate in a chemical mechanical polishing (CMP) process, a thickness of a remaining thin film on the wafer substrate is measured using a spectral signal, and a signal used for the measurement may include various noises. These noises interfere with accurate measurement of the thickness of the wafer substrate. A technology proposed below may increase accuracy of the thickness measurement for the wafer substrate by effectively removing such noises included in the spectral signal.

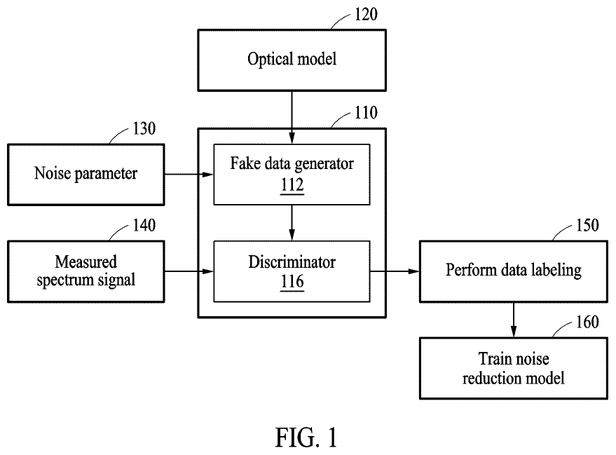

FIG. 1 is a diagram illustrating an overview of a training process according to an embodiment.

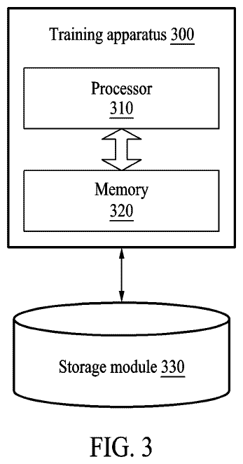

Referring to FIG. 1, a training apparatus (e.g., a training apparatus 300 of FIG. 3) may train a noise reduction model that is used to reduce a noise from a spectrum signal including thickness information of a wafer substrate. Herein, a term “wafer substrate” may be interchangeable with a “substrate”.

The training apparatus may generate one or more training spectrum signals according to a thickness of the wafer substrate using an optical model (a physical process model) 120. The training spectrum signal is a theoretically generated spectrum signal according to a thickness of a wafer-based thin film using an equation of the optical model 120, and may correspond to theoretical optical model data. The optical model 120 may generate a theoretical training spectrum signal corresponding to a selected thin film thickness of the wafer substrate. The thin film thickness for generating the training spectrum signal may be selected as a specific value within a range of available thin film thicknesses of the wafer substrate or may be randomly selected among thin film thickness values within the range. For example, a value of a thin film thickness corresponding to each of the training spectrum signals generated by the optical model 120 may be selected based on a linear or curved distribution between a minimum thickness value and a maximum thickness value. The training spectrum signal may be theoretically determined for each thin film thickness by the equation, and the optical model 120 may calculate and provide a training spectrum signal corresponding to the selected thin film thickness among the theoretical training spectrum signals according to the thin film thickness.

In an embodiment, the optical model 120 may be a thin film interference-based physical process model. The thin film interference-based physical process model generates an intensity model by overlapping each Gaussian peaks, and may generate training spectrum signals according to a thickness of the wafer substrate by changing and using a thin film interference equation for three-dimensional data according to the thickness of the wafer substrate.

In an embodiment, the optical model 120 may be a sampling-based physical process model. In the sampling-based physical process model, a normalized intensity of an observed value for an entire polishing area of a wafer substrate measured in advance is set as a probability variable, and a probability density function which is a distribution of the probability variable is generated. After generating normalized virtual data using normalization methods such as standardization, minmax, and Hilbert envelope, and the like, the normalized virtual data is sampled by the probability density function of spectrum data measured in advance, thereby generating training spectrum signals. The normalized virtual data in an arbitrary polishing area not measured through the probability density function may also be generated. A sampling method used in the sampling-based physical process model may include rejection sampling, Markov Chain Monte Carlo, and the like.

The generated training spectrum signal may be input to a generative adversarial network (GAN) 110. The GAN 110 may include a fake data generator 112 and a discriminator 116. A noise parameter 130 and the training spectrum signal generated by the optical model 120 may be input to the fake data generator 112, and the fake data generator 112 may apply a noise based on the noise parameter 130 to the training spectrum signal, thereby generating the training spectrum signal having a noise. The training spectrum signal having the noise may correspond to fake data. The fake data generator 112 may generate, using the noise parameter 130, the training spectrum signal having the noise while being similar to the training spectrum signal generated using the optical model 120. The fake data generator 112 may be, for example, a feedforward neural network.

The noise parameter 130 may be, for example, a parameter defining intensity of a noise, characteristics of a noise, and/or a pattern of a noise to be applied to the training spectrum signal. The noise to be applied to the training spectrum signal may be determined by the noise parameter 130. For example, the noise may be generated by a theoretical noise generation model, to which the noise parameter 130 is applied, and the noise generated by the noise generation model may vary according to a value of the noise parameter 130.

The training spectrum signal having the noise generated by the fake data generator 112 may be transmitted to the discriminator 116. The discriminator 116 may determine how similar the training spectrum signal having the noise generated by the fake data generator 112 is to an actually measured spectrum signal 140 including thickness information of the wafer substrate. The measured spectrum signal 140 may be a real spectrum signal measured by a spectroscopic monitoring apparatus for measuring a thickness of a wafer substrate during polishing of the wafer substrate. The measured spectrum signal 140 may be obtained by measuring a spectrum of light reflected from the wafer substrate being polished.

The discriminator 116 may calculate a similarity indicating how similar the training spectrum signal having the noise and the actually measured spectrum signal 140 are to each other, and determine whether the similarity satisfies a set condition. For example, the discriminator 116 may determine whether the similarity is greater than a set threshold value. The discriminator 116 may be implemented as a deep learning model such as, for example, a convolutional neural network (CNN).

In operation 150, when the similarity satisfies the set condition, the training apparatus may perform data labeling for the training spectrum signal having the noise. In an embodiment, the training apparatus may label the noise parameter 130 for the training spectrum signal having the noise. The training apparatus may perform the data labeling based on the training spectrum signals having the noise generated by the GAN 110. A value used for the data labeling may be the noise parameter 130 that is used to generate a training spectrum signal having the corresponding noise. Then, in operation 160, the training apparatus may train the noise reduction model based on the training spectrum signal having the noise.

When the similarity does not satisfy the set condition (e.g., when the similarity is a threshold value or less), the training apparatus may perform the process of generating the training spectrum signal using the optical model 120 again, without performing the data labeling.

As described above, the GAN 110 may provide theoretical training spectrum signals having a noise while being similar to the actually measured spectrum signal 140, and may perform the training process for the noise reduction model based on the training spectrum signals having the noise provided as described above.

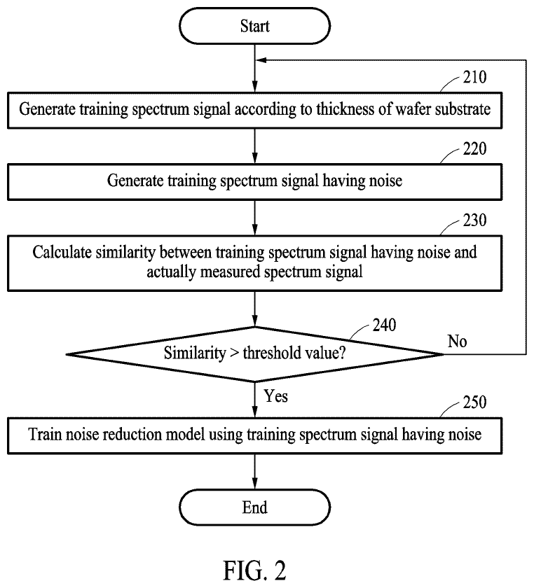

FIG. 2 is a flowchart illustrating operations of a training method according to an embodiment. The training method according to an embodiment may be performed by the training apparatus described herein (e.g., the training apparatus 300 of FIG. 3).

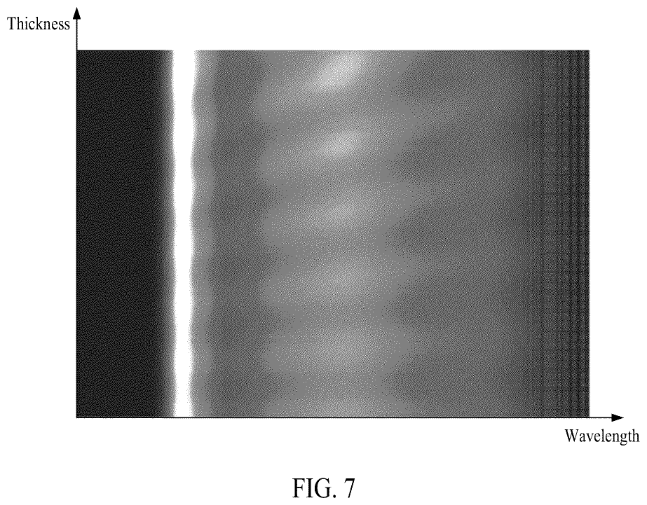

Referring to FIG. 2, in operation 210, the training apparatus may generate a training spectrum signal according to a thickness of a wafer substrate using an optical model (e.g., the optical model 120 of FIG. 1). The training spectrum signal may include spectrum signals according to the thickness of the wafer substrate theoretically generated through the optical model. An example of the training spectrum signal generated by the optical model is shown in FIG. 7. Referring to FIG. 7, the training spectrum signal theoretically generated by the optical model may be expressed by setting, for example, an x axis as a wavelength and a y axis as a thin film thickness of the wafer substrate. The theoretically generated training spectrum signal does not include a noise as shown in FIG. 7.

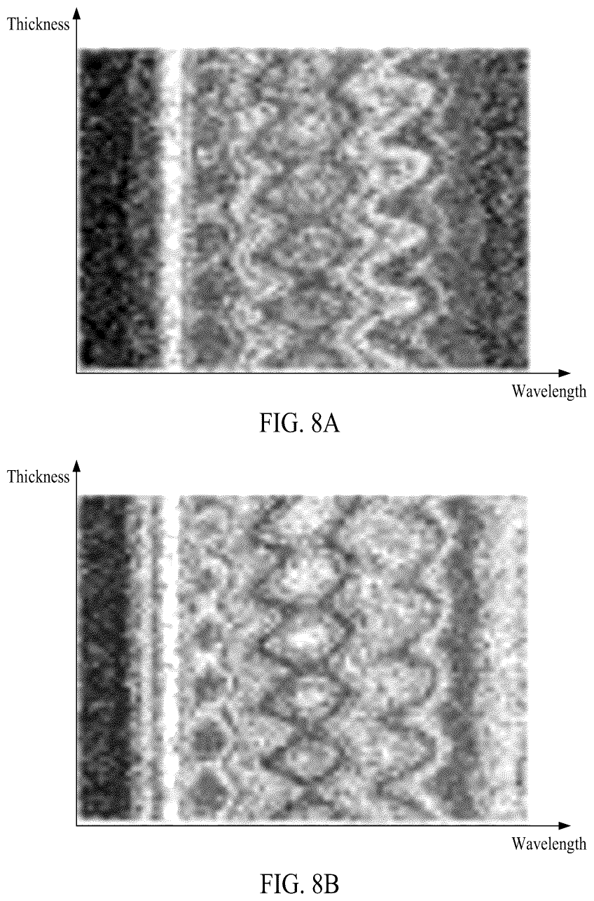

Returning to FIG. 2, in operation 220, the training apparatus may generate a training spectrum signal having a noise by applying a noise based on a noise parameter to the training spectrum signal. In an embodiment, the training apparatus may generate the noise using a noise generation model, to which the noise parameter is applied, and generate the training spectrum signal having the noise by applying the generated noise to the training spectrum signal. Examples of the training spectrum signal having the noise are shown in FIGS. 8A and 8B. Referring to FIGS. 8A and 8B, it is to be understood that information included in a spectrum signal may have an error, because the training spectrum signal having the noise includes the noise, compared to the training spectrum signal shown in FIG. 7.

Returning to FIG. 2 again, in operation 230, the training apparatus may calculate a similarity between the training spectrum signal having the noise and an actually measured spectrum signal. The training apparatus may determine how similar the training spectrum signal having the noise is to the actually measured spectrum signal, and determine the similarity based on how they are similar to each other. Here, the training spectrum signal having the noise and the actually measured spectrum signal to be compared to each other may have the same or similar thickness of the wafer substrate corresponding to the spectrum signal.

Operation 220 of generating the training spectrum signal and operation 230 of calculating the similarity may be performed based on the GAN (e.g., the GAN 110 of FIG. 1). For example, the training apparatus may generate the training spectrum signal having the noise using the fake data generator 112 of FIG. 1, and determine how the training spectrum signal having the noise is to the actually measured spectrum signal using the discriminator 116 of FIG. 1.

In operation 240, the training apparatus may determine whether the similarity calculated in operation 230 satisfies a set condition. For example, the training apparatus may determine whether the similarity is greater than a threshold value by comparing the similarity with the threshold value.

When the similarity satisfies the set condition, for example, when the similarity is greater than the set threshold value, in operation 250, the training apparatus may train a noise reduction model using the training spectrum signal having the noise. The noise reduction model may be a model that estimates a noise parameter related to a noise included in a spectrum signal input to the noise reduction model and outputs the estimated noise parameter. The training apparatus may train the noise reduction model by using, as a label, the noise parameter used to generate the training spectrum signal having the noise.

When it is determined that the similarity does not satisfy the set condition in operation 240, the training apparatus does not perform operation 250 of training the noise reduction model using the training spectrum signal having the noise and may return to operation 210 and perform operations of the training method again.

FIG. 3 is a block diagram illustrating a configuration of a training apparatus according to an embodiment.

Referring to FIG. 3, a training apparatus 300 may include a processor 310 and a memory 320. In some embodiments, at least one of the components may be omitted from the training apparatus 300, or one or more other components may be added to the training apparatus 300. The processor 310 and the memory 320 may communicate with each other via a communication bus. The training apparatus 300 corresponds to the training apparatus described in the present disclosure.

The memory 320 may store information necessary for the processor 310 to perform a processing operation. For example, the memory 320 may store instructions executable by the processor 310, training spectrum signals, actually measured spectrum signals, noise parameters, and the like. The memory 320 may include a volatile memory such as a random-access memory (RAM), a dynamic RAM (DRAM), and a static RAM (SRAM), and/or a non-volatile memory known in the art such as a flash memory.

A storage module 330 may store data related to a GAN (e.g., the GAN 110 of FIG. 1), a noise reduction model, an optical model, and the like. The storage module 330 may include at least one type of storage medium of a flash memory, a hard disk, an SD memory, an XD memory, a magnetic memory, or a magnetic disk. In some embodiments, the storage module 330 may be included in the training apparatus 300 or may be integrated with the memory 320.

The processor 310 may control the overall operation of the training apparatus 300. The processor 310 may include one or more processors, and the processor 310 may include a general-purpose processor such as a central processing unit (CPU), an application processor (AP), or a digital signal processor (DSP), or a neural processing unit (NPU).

The processor 310 may execute the instructions stored in the memory 320 to perform operations of the training apparatus 300 described in the present disclosure. In an embodiment, the instructions executable by the processor 310 and stored in the memory 320 may cause the processor 310 to perform the operations of generating a training spectrum signal according to a thickness of a wafer substrate using an optical model, calculating a training spectrum signal having a noise by applying a noise based on a noise parameter to the training spectrum signal, calculating a similarity between the training spectrum signal having the noise and an actually measured spectrum signal, and, when the similarity satisfies a set condition, training a noise reduction model using the training spectrum signal having the noise. The processor 310 may train the noise reduction model by using, as a label, a noise parameter used to generate the training spectrum signal having the noise. When it is determined that the similarity does not satisfy the set condition, the processor 310 does not train the noise reduction model using the training spectrum signal having the noise and may perform the training process again based on another training spectrum signal.

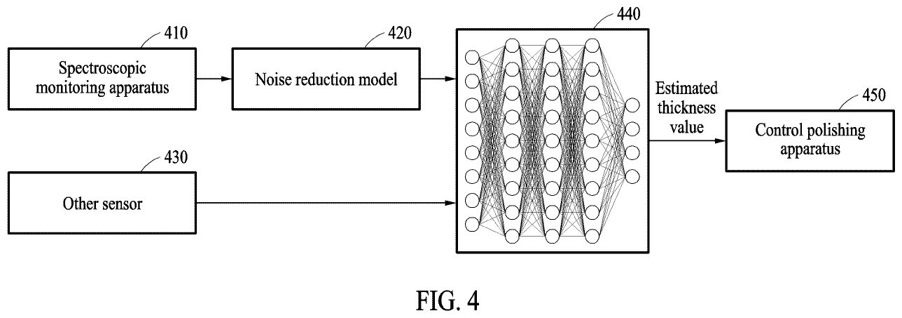

FIG. 4 is a diagram illustrating an overview of a control process of controlling a polishing apparatus for a wafer substrate according to an embodiment.

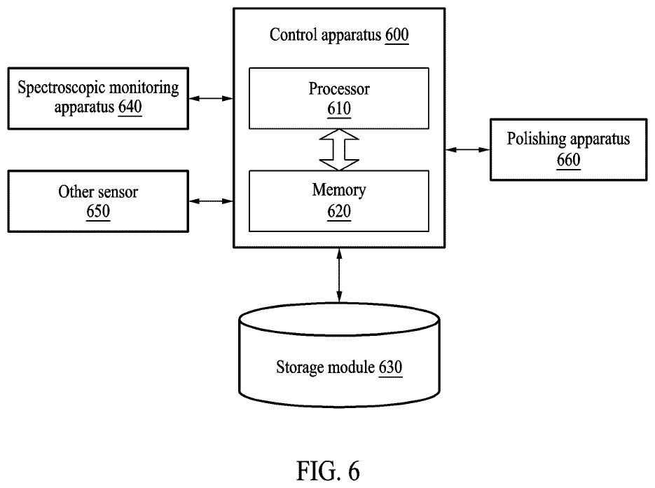

Referring to FIG. 4, a control apparatus (e.g., a control apparatus 600 of FIG. 6) may estimate a thickness of a wafer substrate based on an actual spectrum signal measured to estimate the thickness of the wafer substrate, and control a polishing apparatus for the wafer substrate based on the estimated thickness.

The spectroscopic monitoring apparatus 410 may actually measure and provide a spectrum signal for measuring the thickness (or a thin film thickness) of the wafer substrate being polished by the polishing apparatus. The measured spectrum signal may include information on a thickness of a layer of the wafer substrate. In an embodiment, the spectroscopic monitoring apparatus 410 may include a light source, a photodetector, and a controller. Light emitted from the light source may be reflected by the wafer substrate on a polishing pad, and the light reflected from the wafer substrate may be detected by the photodetector. The photodetector may be a spectrometer. In an embodiment, as the wafer substrate rotates on the polishing pad, the spectrum signals at different positions may be continuously measured according to a sampling frequency. The controller may generate a spectrum signal according to time based on the measured reflected light. Finally, the spectroscopic monitoring apparatus 410 may output the measured spectrum signal including thickness information of the wafer substrate. The measured spectrum signal may be transmitted to a noise reduction model 420.

The control apparatus may perform a noise reduction process for reducing the noise included in the spectrum signal measured by the spectroscopic monitoring apparatus 410 by using the noise reduction model 420. The noise reduction model 420 may include a neural network that, for example, receives the actually measured spectrum signal from the spectroscopic monitoring apparatus 410 and estimates a noise parameter (e.g., a noise index or a noise model-related parameter) of the noise included in the measured spectrum signal. The noise reduction model 420 may determine the noise parameter corresponding to the noise by analyzing the noise included in the measured spectrum signal. The noise reduction model 420 may be trained by, for example, the training process described above with reference to FIGS. 1 to 3. In an embodiment, the noise reduction model 420 generated by completing the training process may set a spectrum signal actually measured during the polishing of the wafer substrate as an input value, and determine a noise index corresponding to the spectrum signal. The noise reduction model 420 may perform a process of reducing the noise included in the measured spectrum signal based on the estimated noise parameter, and output a spectrum signal having the reduced noise.

The control apparatus may determine an estimated thickness value of the wafer substrate by using a thickness estimation model 440 that receives the spectrum signal having the reduced noise as an input. In some embodiments, sensor data output from another sensor 430 (e.g., a temperature sensor, a pressure sensor, or an acceleration sensor) of the polishing apparatus may be input to the thickness estimation model 440 together with the spectrum signal having the reduced noise. The thickness estimation model 440 may estimate the thickness of the wafer substrate based on the input data and output the estimated thickness value.

In an embodiment, the thickness estimation model 440 may be formed based on a neural network including a plurality of input nodes, a plurality of intermediate nodes, and one or more output nodes. Each of the intermediate nodes may be connected to each of the input nodes, and the one or more output nodes may be connected to each of the intermediate nodes. In some embodiments, there may be a plurality of output nodes. The structure of the neural network may be modified in various ways. The spectrum signal having the reduced noise output from the noise reduction model 420 may be input to the input nodes. In some embodiments, sensor data output from the other sensor 430 may be additionally input to the input nodes. Alternatively, in some embodiments, at least one of a previously measured spectrum signal, a measured spectrum signal for another wafer substrate, a polishing parameter used to polish the wafer substrate, a carrier head pressure, or a platen rotation velocity may be additionally input to the input nodes.

In an embodiment, the control apparatus may obtain one of the fake spectrum signals theoretically generated according to the thin film thickness of the wafer substrate that is most similar to the spectrum signal having the reduced noise, and determine an actually estimated thickness value of the wafer substrate based on the thin film thickness corresponding to the obtained fake spectrum signal.

In operation 450, the control apparatus may control the polishing apparatus based on the estimated thickness value for each area of the wafer substrate output from the thickness estimation model 440. The control apparatus may adjust processing parameters of the polishing apparatus or determine a polishing end point to reduce nonuniformity appearing during the polishing process of the wafer substrate based on the estimated thickness value. For example, the control apparatus may detect the polishing end point for the wafer substrate, stop the polishing, or adjust a pressure/rotation velocity applied during the polishing process of the wafer substrate based on the estimated thickness value.

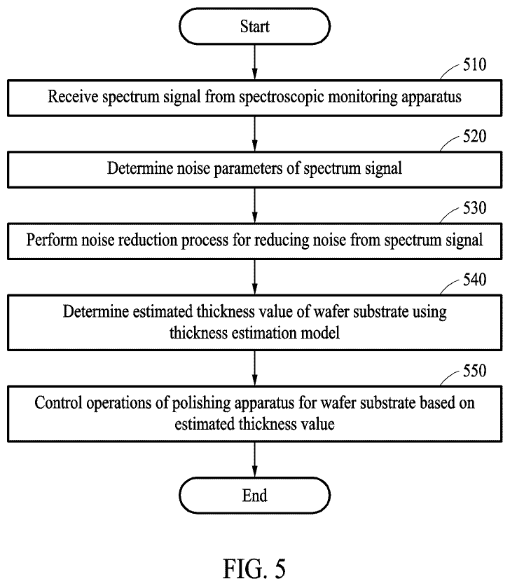

FIG. 5 is a flowchart illustrating operations of a control method according to an embodiment. The control method according to an embodiment may be performed by the control apparatus described herein (e.g., the control apparatus 600 of FIG. 6).

Referring to FIG. 5, in operation 510, the control apparatus may receive a spectrum signal including thickness information of a wafer substrate from a spectroscopic monitoring apparatus (e.g., the spectroscopic monitoring apparatus 410 of FIG. 4).

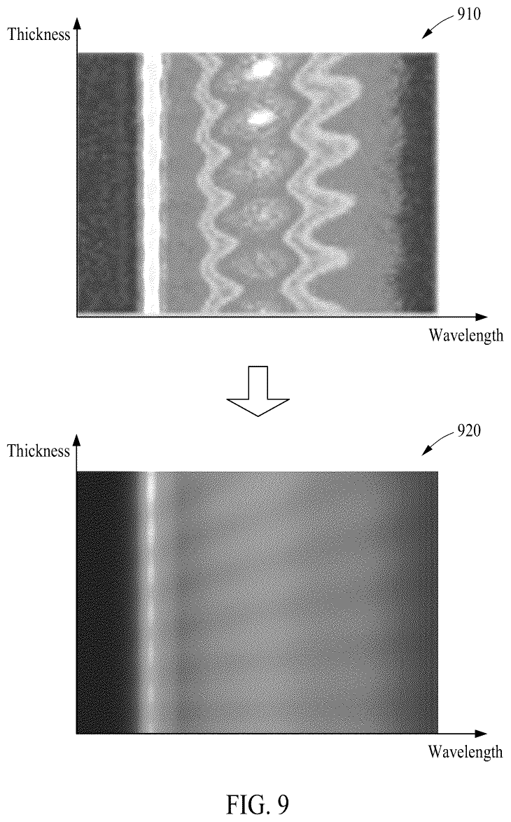

In operation 520, the control apparatus may determine noise parameters for a noise included in the spectrum signal using a noise reduction model that receives the spectrum signal as an input. In operation 530, the control apparatus may perform a noise reduction process for reducing a noise from the spectrum signal based on the determined noise parameters. The noise reduction process may be performed using the noise reduction model, and the noise reduction model may be trained, for example, through the training process of FIG. 2. FIG. 9 is a diagram illustrating a spectrum signal that is actually measured and a resultant signal obtained by performing a noise reduction process using a noise reduction model according to an embodiment. FIG. 9 shows an example of a spectrum signal 910 that is actually measured by the spectroscopic monitoring apparatus, and a resultant signal 920 obtained by performing the noise reduction process on the spectrum signal 910 using the noise reduction model. Through the noise reduction process, the information on the thickness information included in the spectrum signal may be more accurately recognized.

Returning to FIG. 5, in operation 540, the control apparatus may determine an estimated thickness value of the wafer substrate using a thickness estimation model (e.g., the thickness estimation model 440 of FIG. 4) that receives the spectrum signal having the reduced noise as an input. In an embodiment, the thickness estimation model may be formed based on a neural network that receives the spectrum signal having the reduced noise as an input and outputs the estimated thickness value of the wafer substrate based on the input spectrum signal. In an embodiment, the control apparatus may determine a target spectrum signal that is most similar to the spectrum signal having the reduced noise among fake spectrum signals according to the thickness of the wafer substrate that are theoretically generated, and determine a thickness of the wafer substrate corresponding to the target spectrum signal as the estimated thickness value of the wafer substrate.

In operation 550, the control apparatus may control the operations of the polishing apparatus for the wafer substrate based on the estimated thickness value. For example, the control apparatus may end or stop the polishing on the wafer substrate based on the estimated thickness value or may adjust a pressure/rotation velocity applied during the polishing process of the wafer substrate.

FIG. 6 is a block diagram illustrating a configuration of a control apparatus according to an embodiment.

Referring to FIG. 6, the control apparatus 600 may include a processor 610 and a memory 620. In some embodiments, at least one of the components may be omitted from the control apparatus 600, or one or more other components may be added to the control apparatus 600. The processor 610 and the memory 620 may communicate with each other via a communication bus. The control apparatus 600 corresponds to the control apparatus described in the present disclosure.

The memory 620 may store information necessary for the processor 610 to perform a processing operation. For example, the memory 620 may store instructions executable by the processor 610, measured spectrum signals, sensor data, and the like. The memory 620 may include a volatile memory such as a RAM, a DRAM, and a SRAM, and/or a non-volatile memory known in the art such as a flash memory.

A storage module 630 may store data related to a noise reduction model, a thickness estimation model, and polishing-related parameters. The storage module 630 may include at least one type of storage medium of a flash memory, a hard disk, an SD memory, an XD memory, a magnetic memory, or a magnetic disk. In some embodiments, the storage module 630 may be included in the control apparatus 600 or may be integrated with the memory 620.

The processor 610 may control the overall operation of the control apparatus 600. The processor 610 may include one or a plurality of processors, and the processor 610 may include a general-purpose processor such as a CPU, an application processor (AP), or a DSP, or an NPU.

The processor 610 executes instructions stored in the memory 620 to perform operations of the storage device 600 described herein. In an embodiment, the instructions executable by the processor 610 stored in memory 620 may cause the processor 610 to perform operations of receiving a spectrum signal including thickness information of a wafer substrate from a spectroscopic monitoring apparatus 640 (e.g., the spectroscopic monitoring apparatus 410 of FIG. 4), determining a noise parameter for a noise included in the spectrum signal using a noise reduction model configured to receive a spectrum signal as an input, performing a noise reduction process of reducing the noise from the spectrum signal based on the determined noise parameter, and determining an estimated thickness value of the wafer substrate using a thickness estimation model configured to receive a spectrum signal with a reduced noise as an input.

In an embodiment, the processor 610 may determine the estimated thickness value additionally using sensor data from one or more other sensors 650 (e.g., a temperature sensor, pressure sensor, and acceleration sensor) for measuring a state of a polishing apparatus 660.

In an embodiment, the processor 610 may determine a target spectrum signal that is most similar to the spectrum signal having the reduced noise among fake spectrum signals according to the thickness of the wafer substrate that are theoretically generated, and determine a thickness of the wafer substrate corresponding to the target spectrum signal as the estimated thickness value of the wafer substrate.

The processor 610 may control operations of the polishing apparatus 660 of the wafer substrate based on the determined estimated thickness value. For example, the processor 610 may end or stop the polishing on the wafer substrate based on the estimated thickness value or may adjust a pressure/rotation velocity applied during the polishing process of the wafer substrate.

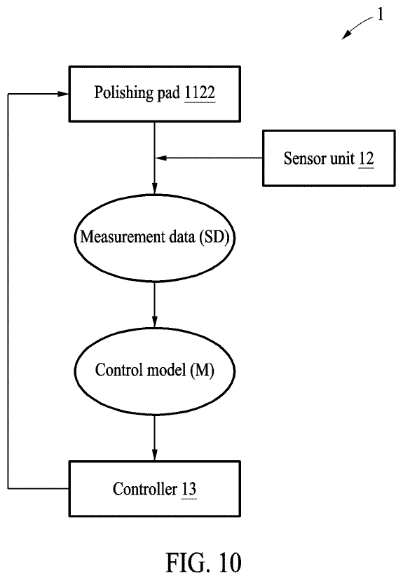

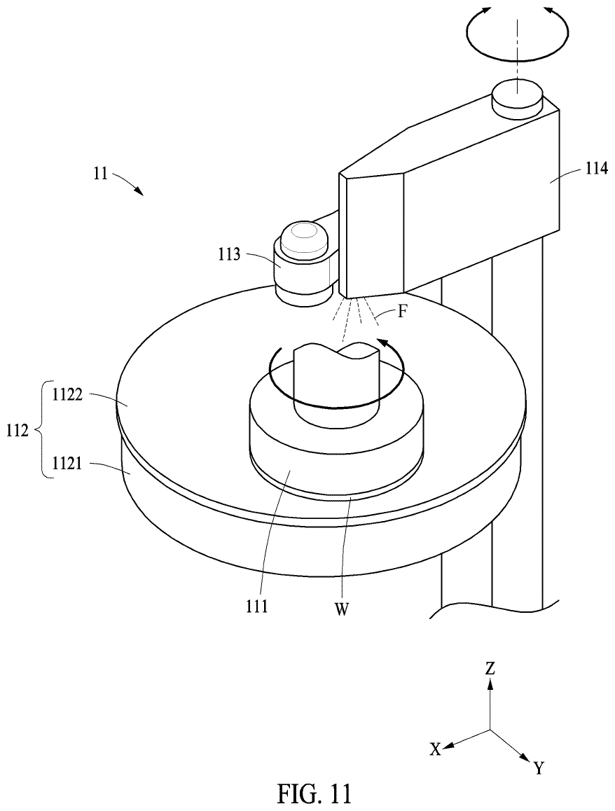

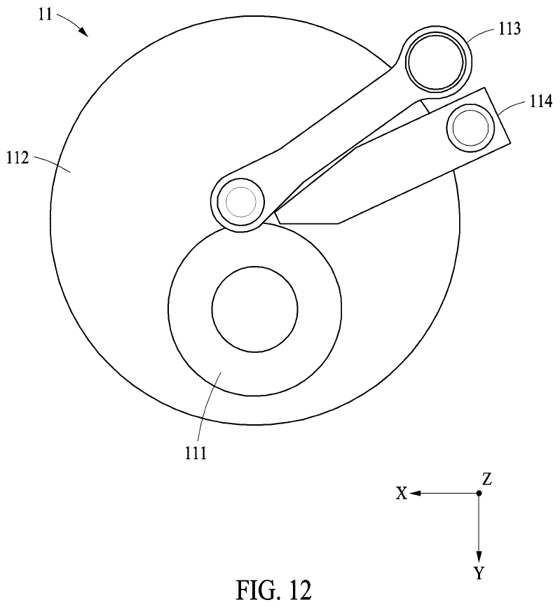

FIG. 10 is a block diagram of a conditioning system for a wafer substrate according to an embodiment. FIG. 11 is a perspective view of a polishing apparatus according to an embodiment and FIG. 12 is a plan view of a polishing apparatus according to an embodiment.

Referring to FIGS. 10, 11, and 12, a conditioning system 1 according to an embodiment may optimize a control model M through machine learning and control a conditioner 113 according to the optimized control model M. The conditioning system 1 according to an embodiment may include a polishing unit 11, a sensor unit 12, and a controller 13. The conditioning system 1 may correspond to the polishing apparatus described herein (e.g., the polishing apparatus 660 of FIG. 6).

The polishing unit 11 may be a mechanism that performs a polishing process on a wafer substrate W. The polishing process for the wafer substrate W may include, not only a process of directly polishing the wafer substrate W, but also a process including both conditioning a polishing pad and supplying a slurry onto the wafer W. In an embodiment, the polishing unit 11 may include a carrier head 111, a polishing plate 112, the conditioner 113, and a slurry supply device 114.

In an embodiment, the carrier head 111 may hold the wafer substrate W. The carrier head 111 may polish the wafer substrate W by pressing a polishing pad 1122, which will be described later, while holding the wafer substrate W. The carrier head 111 may rotate while holding the wafer substrate W. The carrier head 111 may rotate around an axis (e.g., a z-axis) perpendicular to a plane of the wafer substrate W. The carrier head 111 may move in a first direction (e.g., an x-axis direction) and a second direction (e.g., a y-axis direction) perpendicular to the first direction on a plane parallel to the plane of the wafer substrate W. Accordingly, the position of the wafer substrate W may be adjusted above the polishing pad 1122 according to the movement of the carrier head 111.

In an embodiment, the polishing plate 112 may come into contact with the wafer substrate W held by the carrier head 111 and polish the wafer substrate W. The polishing plate 112 may include a rotary table 1121 and the polishing pad 1122.

In an embodiment, the rotary table 1121 may rotate around an axis (e.g., a z-axis) perpendicular to the ground. The polishing pad 1122 may be provided above the rotary table 1121. A surface of the polishing pad 1122 may have grooves formed thereon. The polishing pad 1122 may have an area larger than that of the wafer substrate W. While the wafer substrate W is being polished, the wafer substrate W may come into contact with a local point of the polishing pad 1122.

In an embodiment, the conditioner 113 may condition the surface of the polishing pad 1122. As the polishing is performed, the surface of the polishing pad 1122 may be worn, and for example, the grooves formed on the surface of the polishing pad 1122 may be flattened. The wear of the grooves reduces polishing efficiency of the wafer substrate W, and therefore, the conditioner 113 may restore the surface of the polishing pad 1122 to have a sufficient roughness through a regeneration operation of scraping the surface of the polishing pad 1122. The conditioner 113 may include a conditioning pad coming into contact with the polishing pad 1122 and a conditioning head for rotating the conditioning pad with respect to the polishing pad 1122.

In an embodiment, the slurry supply device 114 may spray a slurry onto the polishing pad 1122. A chemical polishing process of chemically polishing a surface portion of the wafer substrate W as chemical components included in the sprayed slurry chemically react with the surface of the wafer substrate W may be performed.

The sensor unit 12 may measure the surface state of the polishing pad 112. For example, the surface state of the polishing pad 1122 may be a profile of the polishing pad 1122. For example, the sensor unit 12 may include at least one of an acceleration sensor, an optical sensor, a pressure sensor, a motor torque sensor, or an electromagnetic field sensor. However, the type of sensor unit 12 is not limited thereto. Measurement data SD measured by the sensor unit 12 may be measured in real time. In an embodiment, the sensor unit 12 may include a spectroscopic monitoring apparatus configured to generate a spectrum signal to measure a thin film thickness (or a thickness) of the wafer substrate W.

The controller 13 may control the conditioner 113 according to the control model M. In an embodiment, the control model M may use at least one of a pressure applied to the conditioner 113, a rotation speed of the conditioner 113, or a contact time between the conditioner 113 and the polishing pad 1122 as a variable. Accordingly, the controller 13 may control at least one of the pressure applied to the conditioner 113, the rotation speed of the conditioner 113, and the contact time between the conditioner 113 and the polishing pad 1122. In an embodiment, the operation of the controller 13 may be performed by the control apparatus described herein (e.g., the control apparatus 600 of FIG. 6).

According to the embodiments of the present disclosure described above, as the training is performed by labeling a noise parameter (or a noise indicator) in a case of performing the training by adding a noise (or a noise signal) to a theoretical training spectrum signal generated by an optical model, the noise parameter (or the noise indicator) of noises included in a spectrum signal actually measured during the polishing of a wafer substrate is determined, and the noise is effectively reduced from the actually measured spectrum signal using the determined noise parameter, thereby more accurately estimating a thickness of the wafer substrate based on the spectrum signal.

In addition, according to the embodiments described above, the noise may be effectively reduced from the spectrum signal actually generated during the polishing of the wafer substrate, and the actual spectrum signal used in the estimation of the thickness of the wafer substrate may be corrected (or changed) to be very similar to the theoretical spectrum signal, thereby estimating the thickness of the wafer substrate with very high accuracy.

In addition, according to the embodiments described above, since a noise reduction model may be effectively trained even with a small number of pieces of training data, a more accurate noise reduction model may be generated with a smaller number of pieces of training data, and therefore, the cost and time necessary for constructing a thickness estimation system of a wafer substrate may be significantly reduced.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as ROM, RAM, flash memory (e.g., USB flash drives, memory cards, memory sticks, etc.), and the like. Examples of program instructions include both machine code, such as produced by a compiler, and files containing higher level code that may be executed by the computer using an interpreter. The devices described above may be configured to act as one or more software modules in order to perform the operations of the embodiments, or vice versa.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software may also be distributed over network coupled computer systems so that the software is stored and executed in a distributed fashion. The software and data may be stored by one or more non-transitory computer readable recording mediums.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A training method comprising:
generating a training spectrum signal according to a thickness of a wafer substrate using an optical model;
generating a training spectrum signal having a noise by applying a noise based on a noise parameter to the training spectrum signal;
calculating a similarity between the training spectrum signal having the noise and an actually measured spectrum signal; and
when the similarity satisfies a set condition, training a noise reduction model using the training spectrum signal having the noise.

2. The training method of claim 1, wherein the training spectrum signal comprises spectrum signals according to the thickness of the wafer substrate that are theoretically generated through the optical model.

3. The training method of claim 1, wherein the generating of the training spectrum signal having the noise comprises:
generating the noise using a noise generation model; and
generating the training spectrum signal having the noise by applying the generated noise to the training spectrum signal.

4. The training method of claim 1, wherein the training comprises:
training the noise reduction model using, as a label, the noise parameter used to generate the training spectrum signal having the noise.

5. The training method of claim 1, wherein the noise reduction model is configured to estimate a noise parameter related to a noise included in a spectrum signal input to the noise reduction model, and output the estimated noise parameter.

6. The training method of claim 1, wherein the generating of the training spectrum signal and the calculating of the similarity are performed based on a generative adversarial network (GAN).

7. The training method of claim 1, further comprising:
when the similarity does not satisfy the set condition, performing the operations of the training method again without performing the training using the training spectrum signal having the noise.

8. The training method of claim 1, wherein a case in which the similarity satisfies the set condition corresponds to a case in which the similarity is greater than a set threshold value.

9. A control method comprising:
receiving a spectrum signal including thickness information of a wafer substrate from a spectroscopic monitoring device;
determining a noise parameter for a noise included in the spectrum signal using a noise reduction model configured to receive the spectrum signal as an input;
performing a noise reduction process of reducing a noise from the spectrum signal based on the determined noise parameter; and
determining an estimated thickness value of the wafer substrate using a thickness estimation model configured to receive the spectrum signal having the reduced noise as an input.

10. The control method of claim 9, wherein the determining of the estimated thickness value comprises:
determining a target spectrum signal that is most similar to the spectrum signal having the reduced noise among theoretically generated fake spectrum signals according to a thickness of the wafer substrate; and
determining a thickness of the wafer substrate corresponding to the target spectrum signal as the estimated thickness value of the wafer substrate.

11. The control method of claim 9, further comprising:
controlling operations of a polishing apparatus for the wafer substrate based on the determined estimated thickness value.

12. The control method of claim 9, wherein the noise reduction model is trained through the operations of:
generating a training spectrum signal according to a thickness of a wafer substrate using an optical model;
generating a training spectrum signal having a noise by applying a noise based on a noise parameter to the training spectrum signal;
calculating a similarity between the training spectrum signal having the noise and an actually measured spectrum signal; and
when the similarity satisfies a set condition, training the noise reduction model using the training spectrum signal having the noise.

13. A training apparatus comprising:
a processor; and
a memory configured to store instructions executable by the processor,
wherein the executable instructions cause the processor to perform a plurality of operations comprising:
generating a training spectrum signal according to a thickness of a wafer substrate using an optical model;
generating a training spectrum signal having a noise by applying a noise based on a noise parameter to the training spectrum signal;
calculating a similarity between the training spectrum signal having the noise and an actually measured spectrum signal; and
when the similarity satisfies a set condition, training a noise reduction model using the training spectrum signal having the noise.

14. The training apparatus of claim 13, wherein the training spectrum signal comprises spectrum signals according to the thickness of the wafer substrate that are theoretically generated through the optical model.

15. The training apparatus of claim 13, wherein the training comprises:
training the noise reduction model using, as a label, the noise parameter used to generate the training spectrum signal having the noise.

16. The training apparatus of claim 13, wherein the noise reduction model is configured to estimate a noise parameter related to a noise included in a spectrum signal input to the noise reduction model, and output the estimated noise parameter.

17. A control apparatus comprising:
a processor; and
a memory configured to store instructions executable by the processor,
wherein the executable instructions cause the processor to perform a plurality of operations comprising:
receiving a spectrum signal including thickness information of a wafer substrate from a spectroscopic monitoring device;
determining a noise parameter for a noise included in the spectrum signal using a noise reduction model configured to receive the spectrum signal as an input;
performing a noise reduction process of reducing a noise from the spectrum signal based on the determined noise parameter; and
determining an estimated thickness value of the wafer substrate using a thickness estimation model configured to receive the spectrum signal having the reduced noise as an input.

18. The control apparatus of claim 17, wherein the determining of the estimated thickness value comprises:
determining a target spectrum signal that is most similar to the spectrum signal having the reduced noise among theoretically generated fake spectrum signals according to a thickness of the wafer substrate; and
determining a thickness of the wafer substrate corresponding to the target spectrum signal as the estimated thickness value of the wafer substrate.

19. The control apparatus of claim 17, wherein the plurality of operations further comprises:
controlling operations of a polishing apparatus for the wafer substrate based on the determined estimated thickness value.
